(19) United States
(12) Patent Application Publication
(10) Pub. No.: US 2020/0027735 A1
(43) Pub. Date: Jan. 23, 2020

(54) SEMICONDUCTOR STRUCTURE AND METHOD FOR FORMING SAME

(71) Applicant: Semiconductor Manufacturing International (Beijing) Corporation, Beijing (CN)

(72) Inventor: Nan Wang, SHANGHAI (CN)

(73) Assignee: Semiconductor Manufacturing International (Beijing) Corporation, Beijing (CN)

(21) Appl. No.: 16/428,068

(22) Filed: May 31, 2019

(30) Foreign Application Priority Data
Jul. 18, 2018 (CN) 201810792703.0

(51) Int. Cl. H01L 21/033; H01L 21/308; H01L 21/311; H01L 21/3105

(52) U.S. Cl. CPC H01L 21/0332; H01L 21/0337; H01L 21/31053; H01L 21/31144; H01L 21/3086

(57) ABSTRACT

A semiconductor structure and a method for forming same are provided. The forming method includes: providing a base; forming a core layer on the base; forming sacrificial spacers on sidewalls of the core layer, the sacrificial spacer located on one side of the core layer being a first sacrificial spacer, the sacrificial spacer located on the other side of the core layer being a second sacrificial spacer; forming a first mask spacer on a sidewall of the first sacrificial spacer; removing the core layer, and forming an opening in the sacrificial spacers; forming a second mask spacer on a sidewall of the second sacrificial spacer exposed by the opening; removing the sacrificial spacers; and etching the base using the first mask spacer and the second mask spacer as masks to form a target pattern. The present disclosure reduces the process difficulty of a photolithography process, improves operability of the process, and also helps ensure that the shape and size of the target pattern can meet process requirements, so that device performance and performance uniformity can be improved.

### RELATED APPLICATIONS

The present application claims priority to Chinese Patent Appln. No. 201810792703.0, filed Jul. 18, 2018, the entire disclosure of which is hereby incorporated by reference.

### BACKGROUND

### Technical Field

The present disclosure relates to the field of semiconductor manufacturing, and in particular, to a semiconductor structure and a method for forming same.

### Related Art

As a common patterning method, the photolithography technique is a critical production technique in the semiconductor manufacturing process. As semiconductor process nodes become smaller continuously, the self-aligned double patterning (“SADP”) method becomes a popular patterning method in recent years. The method can increase the density of patterns formed on a substrate and further reduce a pitch between two adjacent patterns, so that the photolithography process can break through the resolution limit of photolithography.

With the continuous decrease in the critical dimension (“CD”) of a pattern, the self-aligned quadruple patterning (“SAQP”) method emerges. The density of patterns formed on a substrate using the SADP method is twice that of patterns formed on a substrate using a photolithography process, that is, a minimum ½ pitch can be achieved. Without changing the current photolithography technique (that is, without changing a window size of the photolithography), the density of patterns formed on a substrate using the SAQP method is four times that of patterns formed on a substrate using the photolithography process, that is, a minimum ¼ pitch can be achieved. Therefore, the density of a semiconductor integrated circuit can be greatly improved and a critical dimension of a pattern can be reduced, thereby helping improve device performance.

However, after the SAQP method is used, the device performance and performance uniformity still need to be improved.

### SUMMARY

A problem addressed by the present disclosure is to provide a semiconductor structure and a method for forming same, so as to improve device performance and performance uniformity.

In order to address the foregoing problem, the present disclosure provides a method for forming a semiconductor structure, including: providing a base; forming a core layer on the base; forming sacrificial spacers on sidewalls of the core layer, the sacrificial spacer located on one side of the core layer being a first sacrificial spacer, the sacrificial spacer located on the other side of the core layer being a second sacrificial spacer; forming a first mask spacer on a sidewall of the first sacrificial spacer; removing the core layer after forming the first mask spacer, and forming, in the sacrificial spacers, an opening that exposes the base; forming a second mask spacer on a sidewall of the second sacrificial spacer exposed by the opening; removing the sacrificial spacers after forming the second mask spacer; and after removing the sacrificial spacers, etching the base using the first mask spacer and the second mask spacer as masks to form a target pattern.

Correspondingly, the present disclosure further provides a semiconductor structure, including: a base; a plurality of discrete sacrificial spacers located on the base; and a plurality of mask spacers respectively located on sidewalls of the plurality of discrete sacrificial spacers, where the sidewalls are located on the same side of the sacrificial spacers.

Compared with the prior art, the technical solution of the present disclosure has the following advantages:

In the present disclosure, sacrificial spacers are formed on sidewalls of each core layer, the sacrificial spacer located on one side of the core layer being a first sacrificial spacer, the sacrificial spacer located on the other side of the core layer being a second sacrificial spacer, the first sacrificial spacers and the second sacrificial spacers being arranged alternately; a first mask spacer is formed on a sidewall of the first sacrificial spacer; the core layer is removed after the first mask spacer is formed, and an opening that exposes the base is formed in the sacrificial spacers; and a second mask spacer is formed on a sidewall of the second sacrificial spacer exposed by the opening. In the field of semiconductors, in order to form the first mask spacer on the sidewall of the first sacrificial spacer, deposition, photolithography and etching procedures are usually used. That is, the first mask spacer is also formed on the sidewall of the second sacrificial spacer. Correspondingly, the first mask spacer on the sidewall of the second sacrificial spacer needs to be removed through a photolithography process and an etching process. Similarly, in order to form the second mask spacer on the sidewall of the second sacrificial spacer exposed by the opening, the deposition, photolithography and etching procedures are also used. That is, the second mask spacer is further formed on the sidewall of the first sacrificial spacer exposed by the opening. Correspondingly, the second mask spacer on the sidewall of the first sacrificial spacer also needs to be removed through the photolithography process and the etching process. Therefore, in the present disclosure, the first spacer mask and the second spacer mask are formed successively. Compared with a solution in which target patterns are formed using a conventional SAQP method, and then the target patterns are removed partially through one photolithography process and one etching process to expand a pitch between the remaining adjacent target patterns (for example, after active fins and dummy fins arranged alternately are formed using the SAQP process, the dummy fins are etched through a fin cut process to increase a pitch between adjacent active fins), in the present disclosure, after the base is etched using the first mask spacers and the second mask spacers as masks to form target patterns, a pitch between adjacent target patterns can meet process requirements. Moreover, an opening size of pattern openings in a photoresist layer in each photolithography process can be properly increased, and a pattern pitch of the photoresist layer in each photolithography process can be doubled. Therefore, a precision requirement on the opening size as well as an overlay precision requirement in the photolithography process are lowered correspondingly. This not only reduces the process difficulty of the photolithography process and improves the process operability, but also helps ensure that the shape and size of the target pattern can meet process requirements, so that the device performance and performance uniformity can be improved.

In some forms, when the base is used for forming a SARM device, the first initial mask spacer and the second initial mask spacer are formed successively. This also helps reduce the process difficulty of the photolithography process and improves the process operability correspondingly, and makes the shape and size of the target pattern meet process requirements, thereby helping improve the device performance and performance uniformity of the SRAM device.

In some forms, along an extension direction, the sacrificial spacer has a first end and a second end opposite to each other. When the base is used for forming a SARM device, in the process of forming a first mask spacer, after a first photoresist layer is formed on the base, the first photoresist layer further exposes partial length of the first initial mask spacer which is close to the first end in the first PMOS region. Therefore, the first initial mask spacer on the sidewall of the second sacrificial spacer and the partial length of the first initial mask spacer which is close to the first end in the first PMOS region can be removed in the same process step. Similarly, in the process of forming a second mask spacer, after a second photoresist layer is formed on the base, the second photoresist layer further exposes partial length of the second initial mask spacer which is close to the second end in the second PMOS region. Therefore, the second initial mask spacer on the sidewall of the first sacrificial spacer and the partial length of the second initial mask spacer which is close to the second end in the second PMOS region can be removed in the same process. In conclusion, the present disclosure can reduce the quantity of masks while ensuring the process implementability, thereby reducing process costs of forming a SRAM device and simplifying process steps.

### BRIEF DESCRIPTION OF THE DRAWINGS

FIG. 1 to FIG. 6 are schematic structural diagrams corresponding to steps in a method for forming a semiconductor structure;

FIG. 7 to FIG. 17 are schematic structural diagrams corresponding to steps in one form of a method for forming a semiconductor structure according to the present disclosure;

FIG. 18 to FIG. 24 are schematic structural diagrams corresponding to steps in another form of a method for forming a semiconductor structure;

FIG. 25 is a schematic structural diagram of one form of a semiconductor structure; and

FIG. 26 to FIG. 27 are schematic structural diagrams of another form of a semiconductor structure.

### DETAILED DESCRIPTION

It can be known from the background art that after the SAQP method is used, device performance still needs to be improved. Now, the reason why the device performance still needs to be improved is analyzed with reference to a method for forming a semiconductor structure.

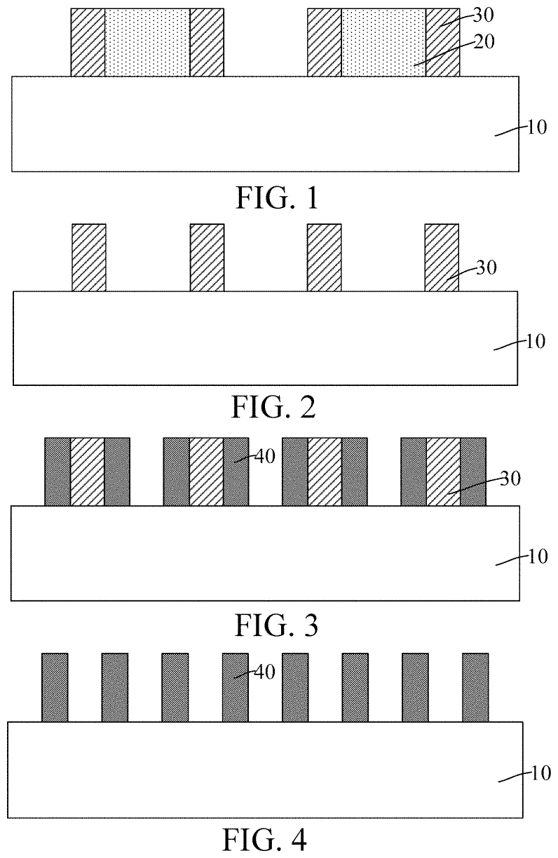

Referring to FIG. 1 to FIG. 6, schematic structural diagrams corresponding to steps in a method for forming a semiconductor structure are shown.

Referring to FIG. 1, a base 10 is provided; a plurality of discrete core layers 20 is formed on the base 10; sacrificial spacers 30 are formed on sidewalls of the core layers 20.

Referring to FIG. 2, after the sacrificial spacers 30 are formed, the core layers 20 (as shown in FIG. 1) are removed.

Referring to FIG. 3, after the core layers 20 (as shown in FIG. 1) are removed, mask spacers 40 are formed on sidewalls of the sacrificial spacers 30.

Referring to FIG. 4, after the mask spacers 40 are formed, the sacrificial spacers 30 (as shown in FIG. 3) are removed.

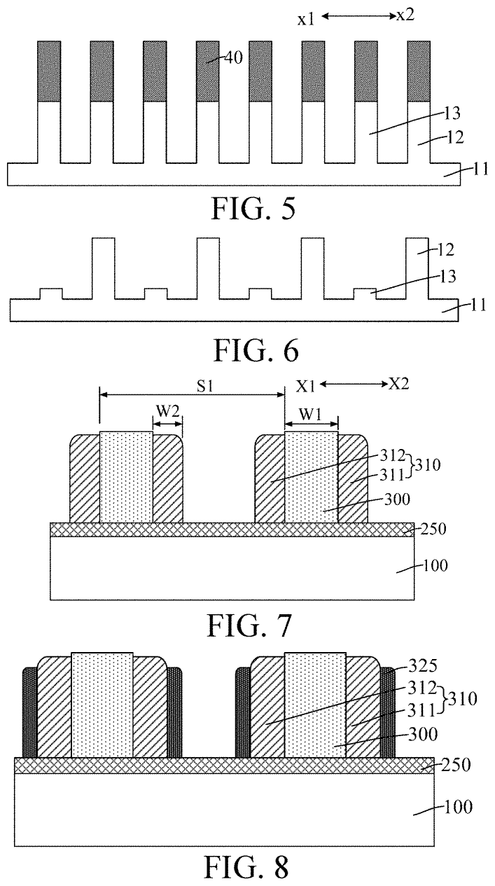

Referring to FIG. 5, the base 10 (as shown in FIG. 4) is etched using the mask spacers 40 as masks, to form a substrate 11 and multiple discrete fins (not marked) protruding from the substrate 11. Among the multiple fins, fins used for forming devices are active fins 12, the remaining fins are dummy fins 13, and the active fins 12 and the dummy fins 13 are arranged alternately.

Therefore, with reference to FIG. 6, after the fins (not marked) are formed, the method further includes: performing etching treatment on the dummy fins 13 to prevent the dummy fins 13 from being used for forming devices. Specifically, the step of performing etching treatment on the dummy fins 13 includes: forming, on the substrate 11, a photoresist layer (not shown) that covers the active fins 12, where pattern openings (not shown) are formed in the photoresist layer, and the pattern openings expose the dummy fins 13; and etching to remove partial thickness of the dummy fins 13 using the photoresist layer as a mask.

After the substrate 11 and the fins are formed, an extension direction of the fin is a first direction (not marked), and a direction that is parallel to the surface of the substrate 11 and perpendicular to the first direction is a second direction (as shown by the direction x1x2 in FIG. 5). As a pattern critical dimension decreases continuously, the width (not marked) of the fin along the second direction decreases gradually, and a pitch (not marked) between adjacent fins decreases gradually. Therefore, the size of the pattern opening along the second direction also decreases gradually. This requires higher size precision of the pattern opening and higher overlay precision of the photolithography process, and correspondingly reduces the size of a process window for forming the photoresist layer.

During an actual process, once the pattern opening deviates with respect to the dummy fin 13 or the size of the pattern opening changes, it is very likely that the pattern opening exposes the dummy fin 13 incompletely. As a result, a part of the dummy fin 13 is not etched after the etching treatment is performed on the dummy fin 13, that is, the problem of etching residual occurs. It is also likely that the pattern opening exposes the active fin 12. As a result, the etching treatment causes a loss of the exposed active fin 12. All these problems easily cause a decrease in device performance and performance uniformity.

In order to address the technical problems, the present disclosure uses two photolithography processes and two etching processes, to form the first spacer masks and the second spacer masks successively. Compared with a solution in which target patterns are formed using a conventional SAQP method, and then the target patterns are removed partially through one photolithography process and one etching process to expand a pitch between the remaining adjacent target patterns, in the present disclosure, after the base is etched using the first mask spacers and the second mask spacers as masks to form target patterns, a pitch between adjacent target patterns can meet process requirements. Moreover, an opening size of pattern openings in a photoresist layer in each photolithography process can be properly increased, and a pattern pitch in the photoresist layer in each photolithography process can be doubled. Therefore, a precision requirement on the opening size as well as an overlay precision requirement in the photolithography process are lowered correspondingly. This not only reduces the process difficulty of the photolithography process and improves the process operability, but also helps ensure that the shape and size of the target pattern can meet process requirements, so that the device performance and performance uniformity can be improved.

In order to make the foregoing objectives, features and advantages of the present disclosure easier to appreciate, specific forms of the present disclosure are described in detail below with reference to the accompanying drawings.

FIG. 7 to FIG. 17 are schematic structural diagrams corresponding to steps in a form of a method for forming a semiconductor structure.

Referring to FIG. 7, a base (not marked) is provided.

The base is patterned subsequently to form target patterns. In this form, the base includes an initial substrate 100. The initial substrate 100 is patterned subsequently to form a substrate and multiple discrete fins on the substrate.

In this form, a material of the initial substrate 100 is silicon. In some other forms, the material of the initial substrate may also be germanium, silicon germanide, silicon carbide, gallium arsenide, indium arsenide or the like. The initial substrate may also be other types of substrates such as a silicon substrate on an insulator or a germanium substrate on an insulator. The material of the initial substrate may also be a material meeting process requirements or easy to integrate.

In other forms, the initial substrate may further include a first semiconductor layer and a second semiconductor layer epitaxially grown on the first semiconductor layer. The first semiconductor layer is used for providing a process foundation for forming the substrate subsequently. The second semiconductor layer is used for providing a process foundation for forming the fins subsequently.

In this form, the base further includes a hard mask (“HM”) material layer 250 formed on the initial substrate 100. The HM material layer 250 is used for providing a process foundation for forming a patterned HM layer subsequently. The HM layer is used as a mask for etching the initial substrate 100 subsequently.

The HM material layer 250 may be silicon nitride (“SiN”), silicon oxide (“SiO₂”), silicon oxynitride (“SiON”), silicon oxycarbide (“SiOC”), amorphous carbon (“a-C”), silicon oxy-carbonitride (“SiOCN”) or a laminate thereof. In this form, the HM material layer 250 is of an oxide-nitride-oxide (“ONO”) structure. That is, the HM material layer 250 includes a first silicon oxide layer located on the initial substrate 100, a silicon nitride layer located on the first silicon oxide layer, and a second silicon oxide layer located on the silicon nitride layer.

It should be appreciated that, in other forms, the base may also include a substrate and a function layer located on the substrate. In the subsequent step of patterning the base, the function layer is patterned.

Still referring to FIG. 7, a plurality of discrete core layers 300 are formed on the base (not marked).

The core layers 300 are used for providing a process foundation for forming first mask spacers and second mask spacers subsequently. The first mask spacers and the second mask spacers are used as masks for patterning the base subsequently. In this form, the core layers 300 are formed on the HM material layer 250.

It should be appreciated that, the core layers 30 will be removed subsequently. Therefore, a material etching selectivity ratio between the core layers 300 and the HM material layer 250 is greater than 50:1, and a material of the core layers 300 is easy to be removed, so as to reduce the damage on the HM material layer 250 caused by the subsequent process of removing the core layers 300.

For this purpose, the material of the core layers 300 may be amorphous silicon, amorphous carbon, amorphous germanium, silicon oxide, silicon oxynitride, silicon nitride, carbon nitride, polycrystalline silicon, silicon carbide, silicon carbonitride, silicon oxy-carbonitride, an organic dielectric layer (“ODL”) material, a dielectric anti-reflective coating (“DARC”) material, or a bottom anti-reflective coating (“BARC”) material. In this form, the material of the core layers 300 is amorphous carbon.

In this form, an extension direction of the core layer 300 is a first direction, and a direction that is parallel to the surface of the base and perpendicular to the first direction is a second direction (as shown by the X1X2 direction in FIG. 7). A width W1 of the core layer 300 along the second direction is determined according to a pitch between subsequent target patterns, and a pitch S1 between the adjacent core layers 300 is also determined according to the pitch between subsequent target patterns. The pitch S1 between the adjacent core layers 300 is twice the pitch between subsequent target patterns.

Still referring to FIG. 7, sacrificial spacers 310 are formed on sidewalls of each core layer 300. A sacrificial spacer 310 located on one side of the core layer 300 is a first sacrificial spacer 311, and a sacrificial spacer 310 located on the other side of the core layer 300 is a second sacrificial spacer 312. The first sacrificial spacers 311 and the second sacrificial spacers 312 are arranged alternately.

The sacrificial spacers 310 are used as a sacrificial layer. The sacrificial spacers 310 occupy part of the base (not marked) exposed by the core layers 300, thereby providing a process foundation for forming first mask spacers and second mask spacers subsequently, so as to define positions of the first mask spacers and the second mask spacers.

It should be appreciated that, in order to reduce the loss of the sacrificial spacers 310 in the subsequent process of removing the core layers 300, an etching selectivity ratio between the core layers 300 and the sacrificial spacers 310 is greater than 20:1. Moreover, the sacrificial spacers 310 will be removed subsequently. Therefore, an etching selectivity ratio between the sacrificial spacers 310 and the HM material layer 250 is greater than 20:1, and a material of the sacrificial spacers 310 is easy to be removed, so as to reduce the damage on the HM material layer 250 caused by the process of removing the sacrificial spacers 310.

For this purpose, the material of the sacrificial spacers 310 may be amorphous silicon, amorphous carbon, amorphous germanium, silicon oxide, silicon oxynitride, silicon nitride, carbon nitride, polycrystalline silicon, silicon carbide, silicon carbonitride, an ODL material, a DARC material, or a BARC material. In this form, the material of the sacrificial spacers 310 is polycrystalline silicon.

In this form, a width W2 of the sacrificial spacer 310 along the second direction is determined according to the pitch between subsequent target patterns and the width W1 of the core layer 300 along the second direction. The sum of the width W2 of the sacrificial spacer 310 and the width W1 of the core layer 300 is equal to the pitch between subsequent target patterns.

In this form, the sacrificial spacers 310 are formed using a deposition process and an etching process. Specifically, the step of forming the sacrificial spacers 310 includes: forming a sacrificial material layer (not shown) that covers the HM material layer 250 as well as the top and sidewalls of the core layers 300, etching to remove the sacrificial material layer located on the HM material layer 250 and the top of the core layers 300, and retaining the remaining sacrificial material layer on the sidewalls of the core layers 300 as the sacrificial spacers 310.

In this form, in order to improve the thickness uniformity of the sacrificial material layer so that the uniformity of the width W2 along the second direction of the sacrificial spacers 310 can be improved, the sacrificial material layer is formed using an atomic layer deposition process. The atomic layer deposition process also helps reduce the difficulty of controlling the thickness of the sacrificial material layer. In other forms, the sacrificial material layer may also be formed using a chemical vapor deposition process.

In this form, an anisotropic blanket dry etch process is used. The sacrificial material layer is etched selectively along the normal direction of the surface of the base, so as to retain the sacrificial material layer on the sidewalls of the core layers 300, thereby forming the sacrificial spacers 310.

Referring to FIG. 8 to FIG. 10 in combination, a first mask spacer 320 (as shown in FIG. 10) is formed on a sidewall of each first sacrificial spacer 311.

The first mask spacer 320 is used as a mask for patterning the base subsequently.

In this form, the first mask spacer 320 is used as a mask for etching the HM material layer 250 and the initial substrate 100 subsequently. Therefore, a material of the first mask spacer 320 is suitable for use as a mask. Moreover, an etching selectivity ratio between the core layer 300 and the first mask spacer 320 is greater than 20:1; an etching selectivity ratio between the sacrificial spacer 310 and the first mask spacer 320 is greater than 20:1, so as to reduce the damage on the first mask spacer 320 caused by the subsequent process of removing the core layer 300 and process of removing the sacrificial spacer 310, thereby ensuring a function of the first mask spacer 320 as an etching mask.

For this purpose, in this form, a material of the first mask spacer 320 is silicon nitride. The silicon nitride material has relatively high hardness and density. The silicon nitride material further helps enhance the function of the first mask spacer 320 as an etching mask. In other forms, according to the materials of the core layer, the sacrificial spacer, the HM material layer and the initial substrate, the material of the first mask spacer may also be amorphous silicon, amorphous carbon, amorphous germanium, silicon oxide, silicon oxynitride, carbon nitride, silicon carbide, silicon carbonitride, silicon oxy-carbonitride, an ODL material, a DARC material or a BARC material.

Correspondingly, a width W3 of the first mask spacer 320 along the second direction (as shown by the X1X2 direction in FIG. 7) is equal to a width of a subsequent target pattern along the second direction. In this form, the width W3 of the first mask spacer 320 is equal to a width of a subsequent fin.

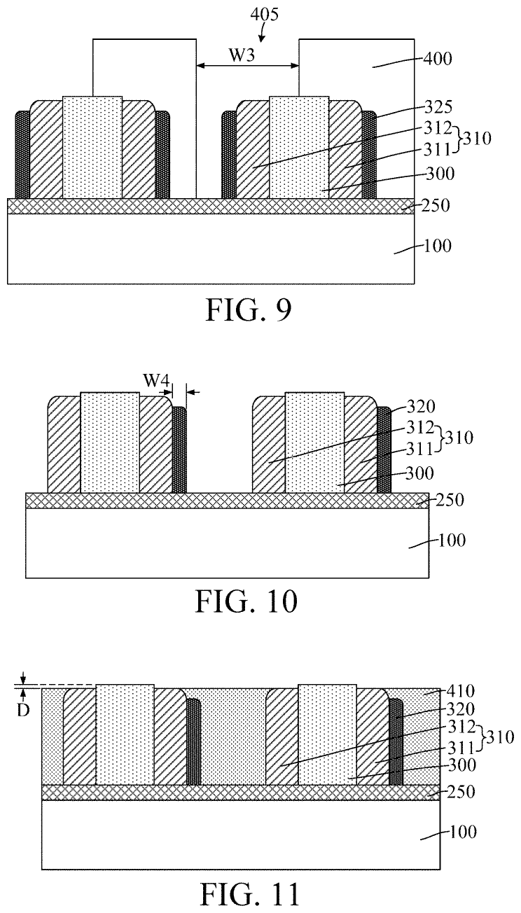

Specifically, the step of forming the first mask spacer 320 includes: as shown in FIG. 8, forming first initial mask spacers 325 on a sidewall of the first sacrificial spacer 311 and a sidewall of the second sacrificial spacer 312; as shown in FIG. 9, forming a first photoresist layer 400 on the HM material layer 250, where the first photoresist layer 400 exposes the first initial mask spacer 325 on the sidewall of the second sacrificial spacer 312; as shown in FIG. 10, using the first photoresist layer 400 (as shown in FIG. 9) as a mask, etching to remove the first initial mask spacer 325 (as shown in FIG. 9) on the sidewall of the second sacrificial spacer 312, and retaining the first initial mask spacer 325 on the sidewall of the first sacrificial spacer 311 as the first mask spacer 320; and removing the first photoresist layer 400 after forming the first mask spacer 320.

It should be appreciated that, the pitch S1 (as shown in FIG. 7) between the adjacent core layers 300 is twice the pitch between subsequent target patterns. The sum of the width W2 (as shown in FIG. 7) of the sacrificial spacer 310 and the width W1 (as shown in FIG. 7) of the core layer 300 is equal to the pitch between subsequent target patterns. Moreover, the first initial mask spacer 325 is formed on the sidewall of the sacrificial spacer 310. Therefore, in order to remove the first initial mask spacer 325 on the sidewall of the second sacrificial spacer 312 and retain the first initial mask spacer 325 on the sidewall of the first sacrificial spacer 311, it is only necessary to ensure that the first photoresist layer 400 can expose the first initial mask spacer 325 on the sidewall of the second sacrificial spacer 312. Compared with a solution in which target patterns are formed using a conventional SAQP method, and then the target patterns are removed partially through one photolithography process and one etching process to expand a pitch between the remaining adjacent target patterns, in this form, in the photolithography process of forming the first photoresist layer 400, the opening size W3 of the first pattern opening 405 along the second direction can be increased properly, and the pattern pitch in the first photoresist layer 400 can be doubled in size. This correspondingly lowers a precision requirement on the opening size W3 and also helps lower an overlay precision requirement in the photolithography process, thereby significantly reducing the process difficulty of the photolithography process, improving the process operability, and also correspondingly improving the shape quality and size precision of the first mask spacer 320.

The process of forming the first initial mask spacer 325 may include an atomic layer deposition process or a chemical vapor deposition process. In this form, the first initial mask spacer 325 is formed using the atomic layer deposition process and the blanket dry etch process. For the specific description about the step of forming the first initial mask spacer 325, reference can be made to the corresponding description about the foregoing step of forming the sacrificial spacers 310, and details are not described herein again.

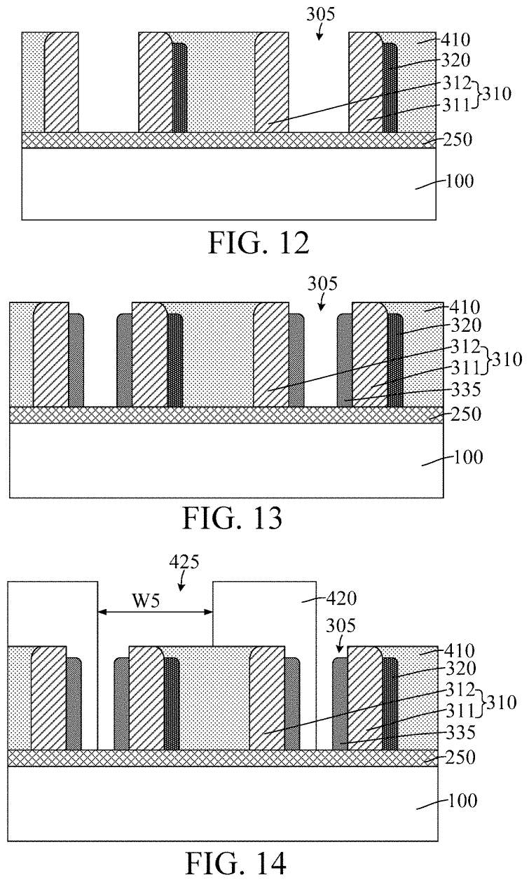

With reference to FIG. 11 and FIG. 12 in combination, after the first mask spacer 320 is formed, the core layer 300 (as shown in FIG. 11) is removed, and an opening 305 (as shown in FIG. 12) that exposes the base is formed in the sacrificial spacers 310.

The opening 305 corresponds to the position of the core layer 300, and the opening 305 is used for providing a spatial position for forming a second mask spacer subsequently.

In this form, in order to improve the speed of removing the core layer 300, etching is performed using a dry etch process to remove the core layer 300.

As shown in FIG. 11, it should be appreciated that, after the first mask spacer 320 is formed and before the core layer 300 is removed, the method further includes: forming a protective layer 410 on the base (not marked), where the protective layer 410 covers the sidewalls of the sacrificial spacers 310 as well as the sidewall and the top of the first mask spacer 320 and exposes the top of the core layer 300.

In the subsequent process of forming the second mask spacers, the protective layer 410 is used for protecting the first mask spacers 320 to reduce the impact of the subsequent process on the first mask spacers 320. The protective layer 410 can further prevent the second mask spacers from being formed on the sidewall, which is away from the core layer 300, of the second sacrificial spacer 312 and on the sidewall of each first mask layer 320.

In this form, by forming the protective layer 410 before removing the core layer 300, the first mask spacer 320 can also be protected in the process of removing the core layer 300, so that the function of the first mask spacer 320 as an etching mask is effectively guaranteed. In addition, after the core layer 300 is removed subsequently, the opening 305 (as shown in FIG. 12) can be formed, thereby reducing the process complexity correspondingly.

A material of the protective layer 410 is a material that can be formed using a process with desirable filling properties. In addition, the protective layer 410 will be removed subsequently. Therefore, the protective layer 410 is made of a material that can be removed easily, so as to reduce the damage on other film structures caused by the subsequent process of removing the protective layer 410. For this purpose, in this form, the material of the protective layer 410 is an ODL material, and the protective layer 410 is formed using a spin coating process. In other forms, the material of the protective layer may also be a BARC material, a DARC material, a DUO material, an APF material or amorphous carbon.

Specifically, the step of forming the protective layer 410 includes: forming a protective material layer on the HM material layer 250, where the protective material layer covers the top of each core layer 300; performing planarization treatment on the protective material layer, so that the remaining protective material layer exposes the top of the core layer 300, where the remaining protective material layer after the planarization treatment is used as the protective layer 410.

In this form, in order to reduce the difficulty of the subsequent process of removing the core layer 300, after the protective layer 410 is formed, the top of the protective layer 410 is lower than the top of the core layer 300. In other forms, the top of the protective layer may also be flush with the top of the core layer.

In this form, a chemical mechanical polishing process is used to perform planarization treatment on the protective material layer. In other forms, an etching process or a combination of a chemical mechanical polishing process and an etching process may also be used to perform planarization treatment on the protective material layer.

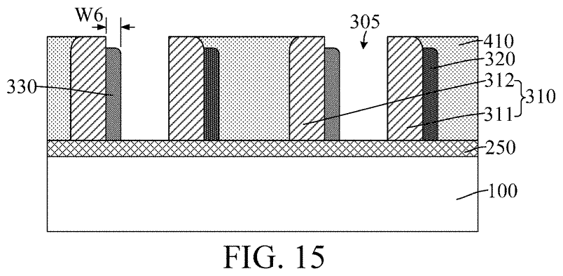

With reference to FIG. 13 to FIG. 15 in combination, a second mask spacer 330 (as shown in FIG. 15) is formed on a sidewall of the second sacrificial spacer 312 which is exposed by the opening 305.

The second mask spacer 330 is also used as a mask for patterning the base subsequently. In this form, the second mask spacer 330 is used as a mask for etching the HM material layer 250 and the initial substrate 100 subsequently.

Therefore, a material of the second mask spacer 330 is suitable for use as a mask. Moreover, an etching selectivity ratio between the sacrificial spacer 310 and the second mask spacer 330 is greater than 20:1, so as to reduce the damage on the second mask spacer 330 caused by the subsequent process of removing the sacrificial spacer 310, thereby ensuring a function of the second mask spacer 330 as an etching mask.

In this form, in order to improve the process compatibility and reduce the process complexity of the subsequent process, the material of the second mask spacer 330 is the same as the material of the first mask spacer 320, that is, the material of the second mask spacer 330 is also silicon nitride. Moreover, the silicon nitride material has relatively high hardness and density, and therefore, the silicon nitride material also helps enhance the function of the second mask spacer 330 as an etching mask.

In other forms, the material of the second mask spacer may also be amorphous silicon, amorphous carbon, amorphous germanium, silicon oxide, silicon oxynitride, carbon nitride, silicon carbide, silicon carbonitride, silicon oxy-carbonitride, an ODL material, a DARC material or a BARC material; the material of the second mask spacer may also be different from the material of the first mask spacer.

In this form, the second mask spacer 330 and the first mask spacer 320 are both used as masks for patterning the base subsequently. Therefore, in order to improve the width uniformity of subsequent target patterns, a width W6 (as shown in FIG. 15) of the second mask spacer 330 along the second direction is equal to a width W4 (as shown in FIG. 10) of the first mask spacer 320 along the second direction.

Specifically, the step of forming the second mask spacer 330 includes: as shown in FIG. 13, forming second initial mask spacers 335 on the sidewall of the first sacrificial spacer 311 and the sidewall of the second sacrificial spacer 312 that are exposed by the opening 305; as shown in FIG. 14, forming a second photoresist layer 420 on the HM material layer 250, where the second photoresist layer 420 exposes the second initial mask spacer 335 on the sidewall of the first sacrificial spacer 311; as shown in FIG. 15, using the second photoresist layer 420 (as shown in FIG. 14) as a mask, etching to remove the second initial mask spacer 335 (as shown in FIG. 14) on the sidewall of the first sacrificial spacer 311, and retaining the second initial mask spacer 335 on the sidewall of the second sacrificial spacer 312 as the second mask spacer 330; and removing the second photoresist layer 420 after forming the second mask spacer 330.

In this form, after the second photoresist layer 420 is formed on the HM material layer 250, second pattern openings 425 are formed in the second photoresist layer 420. It can be known from the foregoing analysis that in the photolithography process of forming the second photoresist layer 420, a precision requirement on an opening size W5 (as shown in FIG. 14) of the second pattern opening 425 along the second direction can be lowered, and an overlay precision requirement in the photolithography process can also be lowered, thereby significantly reducing the process difficulty of the photolithography process, improving the process operability, and improving the shape quality and size precision of the second mask spacer 330.

Therefore, after the base is etched using the first mask spacer 320 and the second mask spacer 330 as masks to form a target pattern, it can be further ensured that the shape and size of the target pattern can meet process requirements, so that device performance and performance uniformity can be improved.

The process for forming the second initial mask spacer 335 may include an atomic layer deposition process or a chemical vapor deposition process. In this form, the second initial mask spacer 335 is formed using an atomic layer deposition process and a blanket dry etch process. For the specific description about the step of forming the second initial mask spacer 335, reference can be made to the corresponding description about the foregoing step of forming the sacrificial spacer 310, and details are not described herein again.

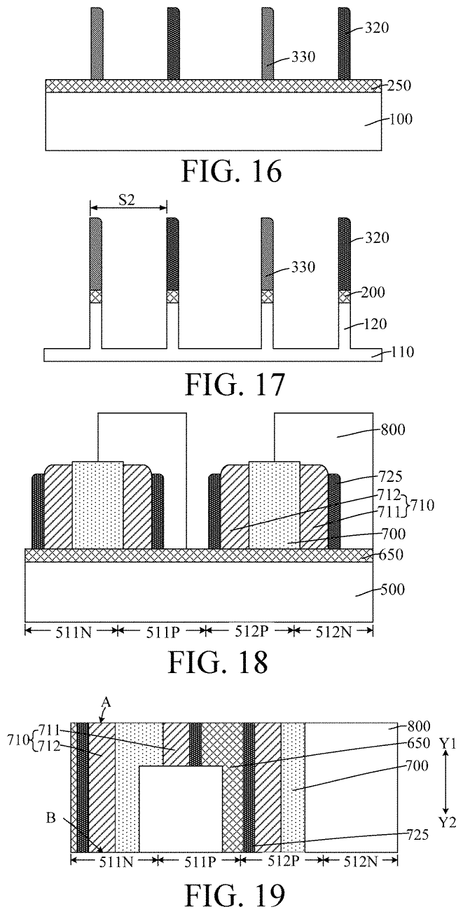

Referring to FIG. 16, after the second mask spacer 330 is formed, the sacrificial spacers 310 (as shown in FIG. 15) are removed.

By removing the sacrificial spacers 310, the surface of the HM material layer 250 is exposed, so as to provide a process foundation for patterning the base subsequently.

In this form, the sacrificial spacers 310 are removed using a wet etch process. Specifically, the material of the sacrificial spacers 310 is polycrystalline silicon, and an etching solution used in the wet etch process is a mixed solution of Cl2 and HBr or a TMAH solution. In other forms, the sacrificial spacers may also be removed using a dry etch process or a process combining dry etch and wet etch.

It should be appreciated that, the protective layer 410 (as shown in FIG. 15) is also formed on the HM material layer 250. Therefore, in order to expose the HM material layer 250 and reduce the process difficulty of removing the sacrificial spacers 310, after the second mask spacer 330 is formed and before the sacrificial spacers 310 are removed, the method further includes: removing the protective layer 410.

In this form, the material of the protective layer 410 is an ODL material. Therefore, the protective layer 410 can be removed using an ashing method.

Referring to FIG. 17, after the sacrificial spacers 310 (as shown in FIG. 15) and the protective layer 410 (as shown in FIG. 15) are removed, the base (not marked) is etched using the first mask spacer 320 and the second mask spacer 330 as masks, to form a target pattern.

In this form, after the base is etched, a substrate 110 and multiple discrete fins 120 protruding from the substrate 110 are formed.

The base includes the initial substrate 100 (as shown in FIG. 16) and the HM material layer 250 (as shown in FIG. 16) located on the initial substrate 100. Therefore, before the initial substrate 100 is etched, the method further includes: etching the HM material layer 250.

Specifically, the HM material layer 250 is etched using the first mask spacer 320 and the second mask spacer 330 as masks to form an HM layer 200; after the HM layer 200 is formed, the initial substrate 100 is further etched using the first mask spacer 320 and the second mask spacer 330 as masks, the remaining initial substrate 100 after etching is used as the substrate 110, and bumps located on the substrate 110 are used as the fins 120. The fins 120 formed after the initial substrate 100 is etched are active fins used for forming devices.

In this form, the material of the HM material layer 250 is silicon nitride, and correspondingly, the material of the HM layer 200 is silicon nitride.

In this form, after the HM layer 200 is formed, the first mask spacer 320 and the second mask spacer 330 are retained; the first mask spacer 320 and the second mask spacer 330 can continue to achieve a function as an etching mask in the process of etching the initial substrate 100. In other forms, according to actual process requirements, the first mask spacer and the second mask spacer may also be removed after the HM layer is formed and before the initial substrate is etched.

The fins 120 and the substrate 110 are of an integrated structure. The fins 120 and the substrate 110 are made of the same material. In this form, the material of the initial substrate 100 is silicon, and correspondingly, the material of the substrate 110 is silicon, and the material of the fins 120 is also silicon.

In other forms, when the initial substrate includes a first semiconductor layer and a second semiconductor layer epitaxially grown on the first semiconductor layer, after the initial substrate is etched, the first semiconductor layer is used as the substrate, and the remaining second semiconductor layer protruding from the first semiconductor layer is used as the fins. Correspondingly, the material of the fins may also be a semiconductor material suitable for forming fins, such as germanium, silicon germanide, silicon carbide, gallium arsenide or indium arsenide; the material of the fins may also be different from the material of the substrate.

In this form, after the initial substrate 100 is etched using the first mask spacer 320 and the second mask spacer 330 as masks, a pitch S2 between the adjacent fins 120 can meet process requirements. Compared with a solution in which active fins and dummy fins arranged alternately are formed using an SAQP process and then the dummy fins are etched using a fin cut process to increase a pitch between adjacent active fins, this form can avoid the problem that partial width of the dummy fin is not etched, and can also avoid the problem that the active fin is damaged during etching. Moreover, in the process of forming the first mask spacer 320 and the second mask spacer 330, the photolithography process has a relatively large process window, so that the shape quality and size of the first mask spacer 320 and the second mask spacer 330 are guaranteed, and it can also be ensured that the shape and size of the fins 120 meet process requirements, thereby improving device performance and performance uniformity.

FIG. 18 to FIG. 24 are schematic structural diagrams corresponding to steps in another form of a method for forming a semiconductor structure.

Identical parts of this form with the foregoing form are not described again herein. The difference of this form from the foregoing form lies in that: the base (not marked) is used for forming a SARM device.

Correspondingly, with reference to FIG. 18, in the step of providing a base (not marked), the base includes a first p-channel metal oxide semiconductor (“PMOS”) region 511P and a second PMOS region 512P adjacent to each other. The base further includes a first n-channel metal oxide semiconductor (“NMOS”) region 511N that is located on a side of the first PMOS region 511P away from the second PMOS region 512P and that is adjacent to the first PMOS region 511P, and a second NMOS region 512N that is located on a side of the second PMOS region 512P away from the first PMOS region 511P and that is adjacent to the second PMOS region 512P.

Specifically, the first PMOS region 511P is used for forming a first pull-up transistor; the second PMOS region 512P is used for forming a second pull-up transistor; the first NMOS region 511N is used for forming a first pull-down transistor and a first gateway transistor; and the second NMOS region 512N is used for forming a second pull-down transistor and a second gateway transistor.

Correspondingly, in the step of forming sacrificial spacers 710 on sidewalls of each core layer 700, the first sacrificial spacer 711 is located on the base of the first PMOS region 511P and the second NMOS region 512N, and the second sacrificial spacer 712 is located on the base of the first NMOS region 511N and the second PMOS region 512P.

In this form, along an extension direction (as shown by the Y1Y2 direction in FIG. 19), the sacrificial spacer 710 has a first end A (as shown in FIG. 19) and a second end B (as shown in FIG. 19) opposite to each other. In order to ensure the normal performance of the SRAM device, according to actual process requirements, after first initial mask spacers 725 (as shown in FIG. 18) are formed on a sidewall of the first sacrificial spacer 711 and a sidewall of the second sacrificial spacer 712, the method further includes: removing partial length of the first initial mask spacer 711 which is close to the first end A in the first PMOS region 511P. Similarly, after second initial mask spacers 735 are formed on the sidewall of the first sacrificial spacer 711 and the sidewall of the second sacrificial spacer 712 that are exposed by the opening 705 (as shown in FIG. 21) in the sacrificial spacers 710, the method further includes: removing partial length of the second initial mask spacer 735 which is close to the second end B in the second PMOS region 512P.

Specific steps of the forming method in this form are described in detail below with reference to the accompanying drawings.

With reference to FIG. 18 and FIG. 19 in combination, FIG. 18 is a cross-sectional view, and FIG. 19 is a top view based on FIG. 18. After the first initial mask spacers 725 (as shown in FIG. 18) are formed on the sidewall of the first sacrificial spacer 711 and the sidewall of the second sacrificial spacer 712, a first photoresist layer 800 is formed on the base, where the first photoresist layer 800 exposes the first initial mask spacer 725 on the sidewall of the second sacrificial spacer 712, and further exposes partial length of the first initial mask spacer 725 which is close to the first end A of the sacrificial spacer 710 in the first PMOS region 511P.

In this form, in the photolithography process of forming the first photoresist layer 800, an opening size of a pattern opening in the first photoresist layer 800 can be increased properly, and a precision requirement on the opening size can be lowered correspondingly. Moreover, it further helps lower an overlay precision requirement in the photolithography process, thereby significantly reducing the process difficulty of the photolithography process and improving the process operability.

Moreover, in this form, the first photoresist layer 800 further exposes partial length of the first initial mask spacer 725 which is close to the first end A in the first PMOS region 511P. In the subsequent etching process, the first initial mask spacer 725 on the sidewall of the second sacrificial spacer 712 and the partial length of the first initial mask spacer 725 which is close to the first end A in the first PMOS region 511P can be removed in the same process correspondingly. The quantity of masks is reduced correspondingly, thereby reducing process costs of forming a SRAM device and simplifying process steps.

In other forms, two masks may be used; the first initial mask spacer on the sidewall of the second sacrificial spacer and the partial length of the first initial mask spacer which is close to the first end in the first PMOS region are separately removed in different process steps.

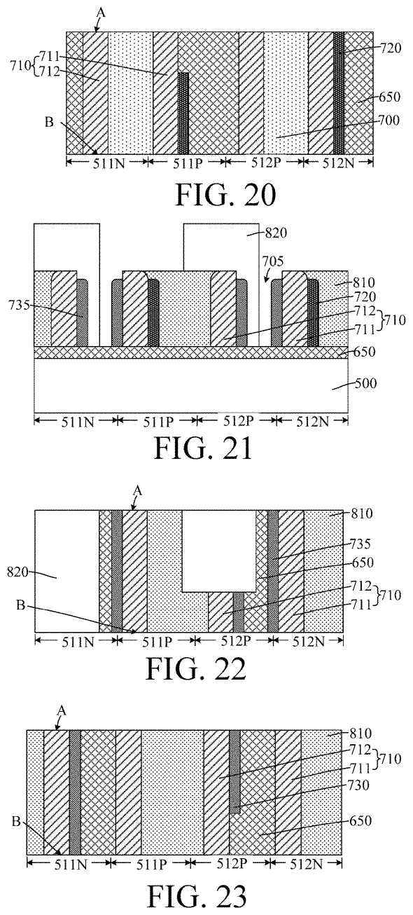

Referring to FIG. 20, FIG. 20 is a top view based on FIG. 19. The first initial mask spacer 725 (as shown in FIG. 19) exposed by the first photoresist layer 800 is removed through etching using the first photoresist layer 800 (as shown in FIG. 19) as a mask. The remaining first initial mask spacer 725 after the etching is used as the first mask spacer 720. The first mask spacer 720 is located on the sidewall of the first sacrificial spacer 711, and the first mask spacer 720 of the first PMOS region 511P exposes a partial sidewall of the first sacrificial spacer 711 which is close to the first end A; after the first mask spacer 720 is formed, the first photoresist layer 800 is removed.

In this form, in the process of forming the first mask spacer 720, the photolithography process has a relatively large process window, so that the shape quality and size of the first mask spacer 720 are guaranteed.

For the specific description about the steps before the first photoresist layer 800 is formed and the specific description about the steps of forming the first photoresist layer 800 and the first mask spacer 720, refer to the corresponding description in the first form. Details are not described in this form again.

Referring to FIG. 21, FIG. 21 is a cross-sectional view based on FIG. 20. After the first mask spacer 720 is formed, a protective layer 810 is formed on the base (not marked), where the protective layer 810 covers the sidewall of the sacrificial spacer 710 as well as the sidewall and the top of the first mask spacer 720, and exposes the top of the core layer 700 (as shown in FIG. 20); after the protective layer 810 is formed, the core layer 700 is removed, and an opening 705 that exposes the base is formed in the sacrificial spacers 710.

For the specific description about the step of forming the protective layer 810 and the specific description about the step of removing the core layer 700, refer to the corresponding description in the first form. Details are not described in this form again.

With reference to FIG. 21 and FIG. 22 in combination, FIG. 21 is a cross-sectional view based on FIG. 20, and FIG. 22 is a top view based on FIG. 21. After the second initial mask spacers 735 are formed on the sidewall of the first sacrificial spacer 711 and the sidewall of the second sacrificial spacer 712 that are exposed by the opening 705, a second photoresist layer 820 is formed on the base (not marked), where the second photoresist layer 820 exposes the second initial mask spacer 735 on the sidewall of the first sacrificial spacer 711 and further exposes partial length of the second initial mask spacer 735 which is close to the second end B of the sacrificial spacer 710 in the second PMOS region 512P.

It can be known from the foregoing analysis that in the photolithography process of forming the second photoresist layer 820, the process difficulty of the photolithography process is also significantly reduced and the process operability is improved. Moreover, the second photoresist layer 820 further exposes partial length of the second initial mask spacer 735 which is close to the second end B in the second PMOS region 512P. In the subsequent etching process, the second initial mask spacer 735 on the sidewall of the first sacrificial spacer 711 and the partial length of the second initial mask spacer 735 which is close to the second end in the second PMOS region 512P can be removed in the same process step correspondingly. The quantity of masks is also reduced correspondingly, thereby reducing process costs of forming a SRAM device and simplifying process steps.

In other forms, two masks may be used; the second initial mask spacer on the sidewall of the first sacrificial spacer and the partial length of the second initial mask spacer which is close to the second end in the second PMOS region are separately removed in different process steps.

Referring to FIG. 23, FIG. 23 is a top view based on FIG. 22. The second initial mask spacer 735 (as shown in FIG. 22) exposed by the second photoresist layer 820 is removed through etching using the second photoresist layer 820 (as shown in FIG. 22) as a mask. The remaining second initial mask spacer 735 after the etching is used as the second mask spacer 730. The second mask spacer 730 is located on the sidewall of the second sacrificial spacer 712 which is exposed by the opening 705 (as shown in FIG. 21), and the second mask spacer 730 of the second PMOS region 512P exposes a partial sidewall of the second sacrificial spacer 712 which is close to the second end B; after the second mask spacer 730 is formed, the second photoresist layer 820 is removed.

In this form, in the process of forming the second mask spacer 730, the photolithography process has a relatively large process window, so that the shape quality and size of the second mask spacer 730 are guaranteed.

For specific description about the steps of forming the second photoresist layer 820 and the second mask spacer 730, refer to the corresponding description in the first form. Details are not described in this form again.

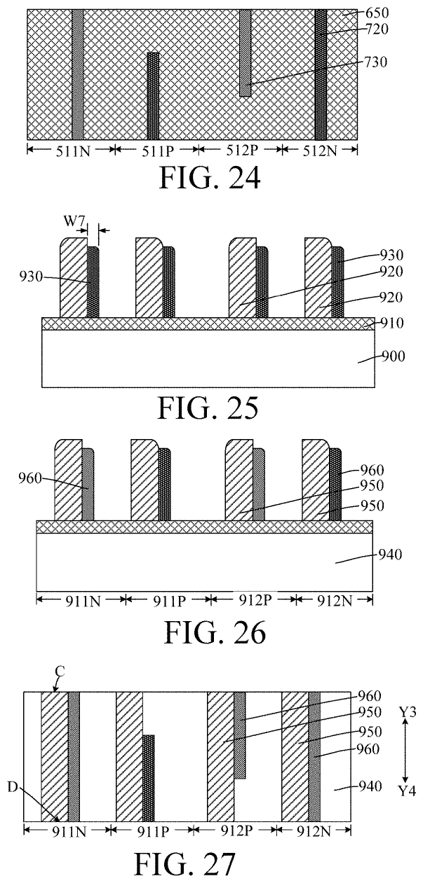

Referring to FIG. 24, FIG. 24 is a top view based on FIG. 23. After the second mask spacer 730 is formed, the protective layer 810 (as shown in FIG. 23) and the sacrificial spacers 710 (as shown in FIG. 23) are removed.

After the protective layer 810 and the sacrificial spacers 710 are removed, the first mask spacer 720 and the second mask spacer 730 expose the HM material layer 650, so as to provide a process foundation for subsequent processes of etching the HM material layer 650 and the initial substrate 500.

Correspondingly, the subsequent process procedure further includes: etching the HM material layer 650 using the first mask spacer 720 and the second mask spacer 730 as masks, to form a patterned HM layer; after the HM layer is formed, continuing to etch the initial substrate 500 (as shown in FIG. 21) using the first mask spacer 720 and the second mask spacer 730 as masks, to form the substrate and multiple discrete fins protruding from the substrate.

In this form, after the initial substrate 500 is etched subsequently using the first mask spacer 720 and the second mask spacer 730 as masks, a pitch between the adjacent fins can meet process requirements. Moreover, by forming the first mask spacer 720 and the second mask spacer 730 successively, it also helps ensure that the shape and size of the fins 120 can meet process requirements, so that device performance and performance uniformity of the SRAM device can be improved.

For the specific description about the forming method in this form, refer to the corresponding description in the first form. Details are not described again in this form.

Correspondingly, the present disclosure further provides a semiconductor structure. Referring to FIG. 25, FIG. 25 is a schematic structural diagram of a semiconductor structure.

The semiconductor structure includes: a base (not marked); a plurality of discrete sacrificial spacers 920 located on the base; and mask spacers 930, each mask spacer 930 being located on one sidewall of the sacrificial spacer 920, and the mask spacers 930 being located on identical sides of the sacrificial spacers 920.

The base is used for providing a process foundation for forming target patterns. Specifically, the target patterns are formed by patterning the base. In this form, the base includes an initial substrate 900, and the initial substrate 900 is patterned subsequently to form a substrate and multiple discrete fins on the substrate.

In this form, a material of the initial substrate 900 is silicon. In some other forms, the material of the initial substrate may also be germanium, silicon germanide, silicon carbide, gallium arsenide, indium arsenide or the like. The initial substrate may also be other types of substrates such as a silicon substrate on an insulator or a germanium substrate on an insulator. The material of the initial substrate may also be a material meeting process requirements or easy to integrate.

In other forms, the initial substrate may further include a first semiconductor layer and a second semiconductor layer epitaxially grown on the first semiconductor layer. The first semiconductor layer is used for providing a process foundation for forming a substrate subsequently. The second semiconductor layer is used for providing a process foundation for forming fins subsequently.

In this form, the base further includes an HM material layer 910 formed on the initial substrate 900. The HM material layer 910 is used for providing a process foundation for forming a patterned HM layer. The HM layer is used as a mask for etching the initial substrate 900.

The HM material layer 910 may be silicon nitride, silicon oxide, silicon oxynitride, silicon oxycarbide, amorphous carbon, silicon oxy-carbonitride or a laminate thereof. In this form, the HM material layer 910 is of an ONO structure. That is, the HM material layer 910 includes a first silicon oxide layer located on the initial substrate 900, a silicon nitride layer located on the first silicon oxide layer, and a second silicon oxide layer located on the silicon nitride layer.

It should be appreciated that, in other forms, the base may also include a substrate and a function layer located on the substrate. In the subsequent step of patterning the base, the function layer is patterned.

The sacrificial spacers 920 are used as a sacrificial layer. The sacrificial spacers 920 occupy part surface of the base (not marked), so as to define positions for forming the mask spacers 930.

It should be appreciated that, the sacrificial spacers 920 will be removed subsequently. Therefore, an etching selectivity ratio between the sacrificial spacers 920 and the HM material layer 910 is greater than 20:1; an etching selectivity ratio between the sacrificial spacers 920 and the mask spacers 930 is greater than 20:1; and a material of the sacrificial spacers 920 is easy to be removed, so as to reduce the damage on the HM material layer 250 and the mask spacers 930 caused by the process of removing the sacrificial spacers 920. For this purpose, the material of the sacrificial spacers 920 may be amorphous silicon, amorphous carbon, amorphous germanium, silicon oxide, silicon oxynitride, silicon nitride, carbon nitride, polycrystalline silicon, silicon carbide, silicon carbonitride, silicon oxy-carbonitride, an ODL material, a DARC material, or a BARC material. In this form, the material of the sacrificial spacers 920 is polycrystalline silicon.

The mask spacers 930 are used as masks for etching the HM material layer 250 and the initial substrate 100. Therefore, the material of the mask spacers 930 is suitable for use as a mask. In this form, the material of the mask spacers 930 is silicon nitride. The silicon nitride material has relatively high hardness and density. The silicon nitride material further helps enhance a function of the mask spacers 320 as an etching mask.

In other forms, according to the materials of the core layer, the sacrificial spacer, the HM material layer and the initial substrate, the material of the mask spacers may also be amorphous silicon, amorphous carbon, amorphous germanium, silicon oxide, silicon oxynitride, carbon nitride, silicon carbide, silicon carbonitride, silicon oxy-carbonitride, an ODL material, a DARC material or a BARC material.

Correspondingly, a width W7 of the mask spacer 930 along a direction perpendicular to the sidewall of the sacrificial spacer 920 is equal to a width of a subsequent target pattern. In this form, the width W7 of the mask spacer 930 is equal to a width of a subsequent fin.

It should be appreciated that, the mask spacer 930 is located on only one sidewall of each sacrificial spacer 920, and after the base is etched using the mask spacers as masks to form a substrate and multiple discrete fins located on the substrate, a pitch between the adjacent fins can meet process requirements. Compared with a solution in which active fins and dummy fins arranged alternately are formed using an SAQP process and then the dummy fins are etched using a fin cut process to increase a pitch between adjacent active fins, this form can avoid the problem that partial width of the dummy fin is not etched, and can also avoid the problem that the active fin is damaged during etching. Device performance and performance uniformity can be improved.

The semiconductor structure can be formed using the forming method in the first form, and may also be formed using other forming methods. For the specific description about the semiconductor structure in this form, reference can be made to the corresponding description in the first form, and details are not described again herein.

Correspondingly, the present disclosure further provides a semiconductor structure. FIG. 26 to FIG. 27 are schematic structural diagrams of another form of a semiconductor structure.

Identical parts of this form with the foregoing form are not described in detail again herein. With reference to FIG. 26 and FIG. 27 in combination, FIG. 26 is a cross-sectional view and FIG. 27 (in which the HM material layer is not shown) is a top view based on FIG. 26. The difference of this form from the foregoing form lies in that: the base (not marked) is used for forming a SARM device.

Correspondingly, with reference to FIG. 26, the base includes a first PMOS region 911P and a second PMOS region 912P that are adjacent to each other; the base further includes a first NMOS region 911N that is located on a side of the first PMOS region 911P away from the second PMOS region 912P and that is adjacent to the first NMOS region 911N, as well as a second NMOS region 912N that is located on a side of the second PMOS region 912P away from the first PMOS region 911P and that is adjacent to the second PMOS region 912P.

Specifically, the first PMOS region 911P is used for forming a first pull-up transistor; the second PMOS region 912P is used for forming a second pull-up transistor; the first NMOS region 911N is used for forming a first pull-down transistor and a first gateway transistor; and the second NMOS region 912N is used for forming a second pull-down transistor and a second gateway transistor. Therefore, the discrete sacrificial spacers 950 are located on the base of the first PMOS region 911P, the second NMOS region 912N, the first NMOS region 911N and the second PMOS region 912P separately.

In this form, along an extension direction (as shown by the Y3Y4 direction in FIG. 27), the sacrificial spacer 950 has a first end C (as shown in FIG. 27) and a second end D (as shown in FIG. 27) opposite to each other. In order to ensure normal performance of the SRAM device, according to actual process requirements, the mask spacer 960 of the first PMOS region 911P exposes a partial sidewall of the sacrificial spacer 950 which is close to the first end C of the sacrificial spacer 950, and the mask spacer 960 of the second PMOS region 912P exposes a partial sidewall of the sacrificial spacer 950 which is close to the second end D of the sacrificial spacer 950.

The mask spacer 960 is located on only one sidewall of each sacrificial spacer 950, and after the initial substrate 940 is etched using the mask spacers 960 as masks, a pitch between the adjacent fins can meet process requirements. Device performance and performance uniformity of the SRAM device can also be improved correspondingly.

The semiconductor structure can be formed using the forming method in the second form, and may also be formed using other forming methods. For the specific description about the semiconductor structure in this form, reference can be made to the corresponding description in the second form, and details are not described again herein.

Although the present disclosure is disclosed above, the present disclosure is not limited thereto. Any person skilled in the art can make various changes and modifications without departing from the spirit and scope of the present disclosure. Therefore, the protection scope of the present disclosure should be subject to the scope defined by the claims.

What is claimed is:

1. A method for forming a semiconductor structure, comprising:
providing a base;
forming a core layer on the base;
forming sacrificial spacers on sidewalls of the core layer, the sacrificial spacer located on one side of the core layer being a first sacrificial spacer, the sacrificial spacer located on the other side of the core layer being a second sacrificial spacer;
forming a first mask spacer on a sidewall of the first sacrificial spacer;
removing the core layer after forming the first mask spacer, and forming, in the sacrificial spacers, an opening that exposes the base;
forming a second mask spacer on a sidewall of the second sacrificial spacer exposed by the opening;
removing the sacrificial spacers after forming the second mask spacer; and
after removing the sacrificial spacers, etching the base using the first mask spacer and the second mask spacer as masks to form a target pattern.

2. The method for forming a semiconductor structure according to claim 1, wherein the step of forming a first mask spacer on a sidewall of the first sacrificial spacer comprises:
forming first initial mask spacers on a sidewall of the first sacrificial spacer and a sidewall of the second sacrificial spacer;
forming a first photoresist layer on the base, the first photoresist layer exposing the first initial mask spacer on the sidewall of the second sacrificial spacer;
etching, using the first photoresist layer as a mask, to remove the first initial mask spacer on the sidewall of the second sacrificial spacer, and retaining the first initial mask spacer on the sidewall of the first sacrificial spacer as the first mask spacer; and
removing the first photoresist layer after forming the first mask spacer.

3. The method for forming a semiconductor structure according to claim 2, wherein in the step of forming first initial mask spacers on a sidewall of the first sacrificial spacer and a sidewall of the second sacrificial spacer, a process for forming the first initial mask spacers comprises an atomic layer deposition process or a chemical vapor deposition process.

4. The method for forming a semiconductor structure according to claim 1, wherein after the forming a first mask spacer on a sidewall of the first sacrificial spacer and before the removing the core layer, the method further comprises: forming a protective layer on the base, the protective layer covering the sidewalls of the sacrificial spacers as well as a sidewall and the top of the first mask spacer and exposing the top of the core layer.

5. The method for forming a semiconductor structure according to claim 4, wherein after the forming a second mask spacer on a sidewall of the second sacrificial spacer exposed by the opening and before the etching the base, the method further comprises: removing the protective layer.

6. The method for forming a semiconductor structure according to claim 4, wherein the step of forming a protective layer on the base comprises:
forming a protective material layer on the base, the protective material layer covering the top of the core layer; and
performing planarization treatment on the protective material layer, so that the remaining protective material layer exposes the top of the core layer, the remaining protective material layer after the planarization treatment being used as the protective layer.

7. The method for forming a semiconductor structure according to claim 1, wherein the step of forming a second mask spacer on a sidewall of the second sacrificial spacer exposed by the opening comprises:
forming second initial mask spacers on the sidewall of the first sacrificial spacer and the sidewall of the second sacrificial spacer that are exposed by the opening;
forming a second photoresist layer on the base, the second photoresist layer exposing the second initial mask spacer on the sidewall of the first sacrificial spacer;
etching, using the second photoresist layer as a mask, to remove the second initial mask spacer on the sidewall of the first sacrificial spacer, and retaining the second initial mask spacer on the sidewall of the second sacrificial spacer as the second mask spacer; and
removing the second photoresist layer after forming the second mask spacer.

8. The method for forming a semiconductor structure according to claim 7, wherein in the step of forming second initial mask spacers on the sidewall of the first sacrificial spacer and the sidewall of the second sacrificial spacer that are exposed by the opening, a process for forming the second initial mask spacers comprises atomic layer deposition process or chemical vapor deposition process.

9. The method for forming a semiconductor structure according to claim 1, wherein a material of any of the core layer, the sacrificial spacer, the first mask spacer and the second mask spacer is amorphous silicon, amorphous carbon, amorphous germanium, silicon oxide, silicon oxynitride, silicon nitride, carbon nitride, polycrystalline silicon, silicon carbide, silicon carbonitride, silicon oxy-carbonitride, an organic dielectric layer (“ODL”) material, a dielectric anti-reflective coating (“DARC”) material or a bottom anti-reflective coating (“BARC”) material.

10. The method for forming a semiconductor structure according to claim 4, wherein a material of the protective layer is a bottom anti-reflective coating (“BARC”) material, an organic dielectric layer (“ODL”) material, a dielectric anti-reflective coating (“DARC”) material, a DUO material, an APF material or amorphous carbon.

11. The method for forming a semiconductor structure according to claim 1, wherein in the step of providing a base, the base comprises an initial substrate; and
the step of etching the base using the first mask spacer and the second mask spacer as masks to form a target pattern comprises: etching the initial substrate using the first mask spacer and the second mask spacer as masks, where the remaining initial substrate after the etching being used as the substrate, and bumps located on the substrate being used as fins.

12. The method for forming a semiconductor structure according to claim 1, wherein in the step of forming sacrificial spacers on sidewalls of each core layer, an extension direction of the sacrificial spacer is a first direction, and a direction that is parallel to the surface of the base and perpendicular to the first direction is a second direction; and
in the step of forming a second mask spacer on a sidewall of the second sacrificial spacer exposed by the opening, a width of the second mask spacer along the second direction is equal to a width of the first mask spacer along the second direction.

13. The method for forming a semiconductor structure according to claim 2, wherein in the step of providing a base, the base is used for forming a SARM device, the base comprises a first p-channel metal oxide semiconductor (“PMOS”) region and a second PMOS region that are adjacent to each other, the base further comprises a first n-channel metal oxide semiconductor (“NMOS”) region that is located on a side of the first PMOS region away from the second PMOS region and that is adjacent to the first PMOS region and a second NMOS region that is located on a side of the second PMOS region away from the first PMOS region and that is adjacent to the second PMOS region, and along an extension direction, each sacrificial spacer has a first end and a second end opposite to each other;
in the step of forming sacrificial spacers on sidewalls of each core layer, the first sacrificial spacer is located on the base of the first PMOS region and the second NMOS region, and the second sacrificial spacer is located on the base of the first NMOS region and the second PMOS region; and
after the forming first initial mask spacers on a sidewall of the first sacrificial spacer and a sidewall of the second sacrificial spacer, the method further comprises: removing partial length of the first initial mask spacer which is close to the first end of the sacrificial spacer in the first PMOS region.

14. The method for forming a semiconductor structure according to claim 13, wherein in the step of forming a first photoresist layer on the base, the first photoresist layer further exposes partial length of the first initial mask spacer which is close to the first end of the sacrificial spacer in the first PMOS region.

15. The method for forming a semiconductor structure according to claim 7, wherein in the step of providing a base, the base is used for forming a SARM device, the base comprises a first p-channel metal oxide semiconductor (“PMOS”) region and a second PMOS region that are adjacent to each other, the base further comprises a first n-channel metal oxide semiconductor (“NMOS”) region adjacent to the first PMOS region and a second NMOS region adjacent to the second PMOS region, and along an extension direction, each core layer has a first end and a second end opposite to each other;
in the step of forming sacrificial spacers on sidewalls of each core layer, the first sacrificial spacer is located on the base of the first PMOS region and the second NMOS region, and the second sacrificial spacer is located on the base of the first NMOS region and the second PMOS region; and
after the forming second initial mask spacers on the sidewall of the first sacrificial spacer and the sidewall of the second sacrificial spacer that are exposed by the opening, the method further comprises: removing partial length of the second initial mask spacer which is close to the second end of the sacrificial spacer in the second PMOS region.

16. The method for forming a semiconductor structure according to claim 15, wherein in the step of forming a second photoresist layer on the base, the second photoresist layer further exposes partial length of the second initial mask spacer which is close to the second end of the sacrificial spacer in the second PMOS region.

17. A semiconductor structure, comprising:
a base;
a plurality of discrete sacrificial spacers located on the base; and
a plurality of mask spacers respectively located on sidewalls of the plurality of discrete sacrificial spacers, wherein the sidewalls being located on the same side of the sacrificial spacers.

18. The semiconductor structure according to claim 17, wherein a material of any of the sacrificial spacer and the mask spacer is amorphous silicon, amorphous carbon, amorphous germanium, silicon oxide, silicon oxynitride, silicon nitride, carbon nitride, polycrystalline silicon, silicon carbide, silicon carbonitride, silicon oxy-carbonitride, an organic dielectric layer (“ODL”) material, a dielectric anti-reflective coating (“DARC”) material or a bottom anti-reflective coating (“BARC”) material.

19. The semiconductor structure according to claim 17, wherein the base comprises an initial substrate.

20. The semiconductor structure according to claim 17, wherein the base is used for forming a SARM device, the base comprises a first p-channel metal oxide semiconductor (“PMOS”) region and a second PMOS region that are adjacent to each other, and the base further comprises a first n-channel metal oxide semiconductor (“NMOS”) region that is located on a side of the first PMOS region away from the second PMOS region and that is adjacent to the first PMOS region as well as a second NMOS region that is located on a side of the second PMOS region away from the first PMOS region and that is adjacent to the second PMOS region, and along an extension direction, each sacrificial spacer has a first end and a second end opposite to each other; and
the mask spacer of the first PMOS region exposes a partial sidewall of the sacrificial spacer which is close to the first end of the sacrificial spacer, and the mask spacer of the second PMOS region exposes a partial sidewall of the sacrificial spacer which is close to the second end of the sacrificial spacer.
